(19) United States
(12) Patent Application Publication
(10) Pub. No.: US 2023/0148222 A1
(43) Pub. Date: May 11, 2023

(54) INTERPOSER STRUCTURE AND SEMICONDUCTOR PACKAGE INCLUDING THE SAME

(71) Applicant: Samsung Electronics Co., Ltd., Suwon-si (KR)

(72) Inventors: Boin Noh, Suwon-si (KR); Jeonghoon Ahn, Seongnam-si (KR)

(21) Appl. No.: 18/050,724

(22) Filed: Oct. 28, 2022

(30) Foreign Application Priority Data
Nov. 8, 2021 (KR) 10-2021-0152568

(51) Int. Cl. H01L 23/498; H01L 23/00; H01L 25/065; H01L 21/48

(52) U.S. Cl. CPC H01L 23/49838; H01L 24/08; H01L 25/0655; H01L 21/486; H01L 21/4857; H01L 23/49816; H01L 23/49822; H01L 23/49833; H01L 23/49894; H01L 2224/08225; H01L 2924/3511; H01L 2924/182; H01L 2924/1616; H01L 2924/16251; H01L 2924/1632

(57) ABSTRACT

An interposer structure includes: an interposer substrate; an interposer through electrode penetrating through the interposer substrate in a vertical direction; a redistribution structure on the interposer substrate and including a redistribution pattern connected to the interposer through electrode and a redistribution insulating layer on side surfaces of the redistribution pattern on the interposer substrate; a conductive post on the redistribution structure and connected to the redistribution pattern; and an interposer insulating layer on side surfaces of the conductive post on the redistribution structure.

### CROSS-REFERENCE TO RELATED APPLICATION

This application is based on and claims priority under 35 U.S.C. § 119 to Korean Patent Application No. 10-2021-0152568, filed on Nov. 8, 2021, in the Korean Intellectual Property Office, the disclosure of which is incorporated by reference herein in its entirety.

### BACKGROUND

The inventive concept relates to a semiconductor package, and more particularly, to a semiconductor package including an interposer structure.

It may be desirable for the storage capacity of a semiconductor device to be increased while also providing a semiconductor package including the semiconductor device that is thin and light-weight. Studies on improving operating speeds of a plurality of semiconductor chips, and studies on improving structural reliability of semiconductor packages are being conducted.

### SUMMARY

The inventive concept provides a semiconductor package in which structural reliability is improved.

Also, the inventive concept provides a semiconductor package in which a time of a manufacturing method is reduced.

According to an aspect of the inventive concept, there is provided an interposer structure including: an interposer substrate; an interposer through electrode extending into the interposer substrate in a vertical direction; a redistribution structure on the interposer substrate including a redistribution pattern connected to the interposer through electrode and a redistribution insulating layer on the interposer substrate and side surfaces of the redistribution pattern; a conductive post on the redistribution structure and connected to the redistribution pattern; and an interposer insulating layer on the redistribution structure and side surfaces of the conductive post.

According to another aspect of the inventive concept, there is provided a semiconductor package including: an interposer structure including: an interposer substrate; an interposer through electrode extending into the interposer substrate in a vertical direction; a redistribution structure on the interposer substrate including a redistribution pattern connected to the interposer through electrode and a redistribution insulating layer on the interposer substrate and side surfaces of the redistribution pattern; a conductive post on the redistribution structure and connected to the redistribution pattern; a chip connection terminal on the conductive post; and an interposer insulating layer on the redistribution structure and on side surfaces of the conductive post and the chip connection terminal; a semiconductor chip on the interposer structure and including: a semiconductor substrate including an active layer; and a chip pad on a lower portion of the semiconductor substrate, connected to the active layer, and contacting the chip connection terminal; and a molding layer on the interposer structure and side surfaces of the semiconductor chip.

According to another aspect of the inventive concept, there is provided a semiconductor package including: a package substrate; an interposer structure on the package substrate and including: an interposer substrate; an interposer through electrode extending into the interposer substrate in a vertical direction; a redistribution structure provided on the interposer substrate and including a redistribution pattern connected to the interposer through electrode and a redistribution insulating layer on the interposer substrate and side surfaces of the redistribution insulating layer; a conductive post on the redistribution structure and connected to the redistribution pattern; a chip connection terminal on the conductive post; an interposer insulating layer on the redistribution structure and side surfaces of the conductive post and the chip connection terminal; and an interposer connection terminal on a lower portion of the interposer substrate and connected to the package substrate; a semiconductor chip on the interposer structure and including: a semiconductor substrate including an active layer; and a chip pad on a lower portion of the semiconductor substrate, connected to the active layer, and contacting the chip connection terminal; a molding layer on the interposer structure and side surfaces of the semiconductor chip; and an underfill layer between the interposer substrate and the package substrate, and on side surfaces of the interposer connection terminal.

A semiconductor package according to an embodiment of the inventive concept includes an interposer insulating layer between a semiconductor substrate and an interposer substrate, and thus a warpage of the semiconductor package, which occurs due to a difference of coefficients of thermal expansion between the semiconductor substrate and the interposer substrate during a thermal compression bonding process of mounting a semiconductor chip on an interposer structure, may be improved. Accordingly, a bonding defect of the semiconductor package may be improved and structural reliability of the semiconductor package may be improved.

In addition, according to a method of manufacturing a semiconductor package of the inventive concept, a process of forming an underfill layer in a space between a plurality of semiconductor chips and an interposer structure may be omitted. Accordingly, a time of the method of manufacturing a semiconductor package of the inventive concept may be reduced.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of an interposer structure according to an embodiment of the inventive concept;

FIG. 2 is a cross-sectional view of a semiconductor package according to an embodiment of the inventive concept;

FIG. 3 is an enlarged view of a region A in FIG. 2;

FIGS. 4A through 4C are cross-sectional views taken along a line IV-IV′ of FIG. 2;

FIG. 5 is a cross-sectional view of a semiconductor package according to a comparative example;

FIG. 6 is a cross-sectional view of an interposer structure according to an embodiment of the inventive concept;

FIG. 7 is a cross-sectional view of a semiconductor package according to an embodiment of the inventive concept;

FIG. 8 is an enlarged view of a region B in FIG. 7;

FIG. 9 is a cross-sectional view of a semiconductor package according to an embodiment of the inventive concept;

FIG. 10 is a cross-sectional view of a semiconductor package according to an embodiment of the inventive concept;

FIG. 11 is a cross-sectional view of an interposer structure according to an embodiment of the inventive concept;

FIGS. 12A through 12G are views for describing operations of a method of manufacturing a semiconductor package, according to an embodiment of the inventive concept; and

FIGS. 13A through 13E are views for describing operations of a method of manufacturing a semiconductor package, according to an embodiment of the inventive concept.

### DETAILED DESCRIPTION OF THE EMBODIMENTS

Hereinafter, embodiments of the inventive concept will be described in detail with reference to accompanying drawings.

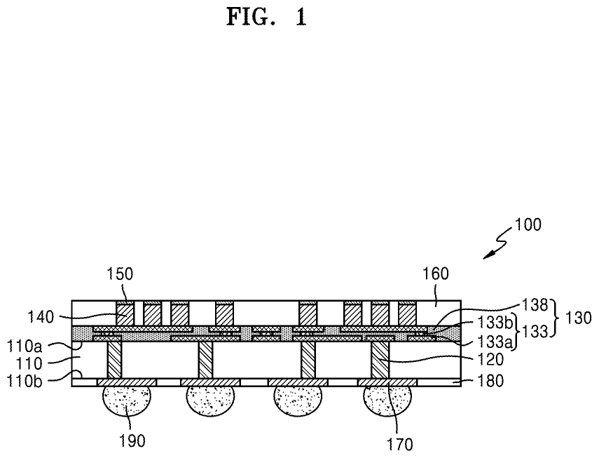

FIG. 1 is a cross-sectional view of an interposer structure 100 according to an embodiment of the inventive concept.

The interposer structure 100 according to an embodiment of the inventive concept may include an interposer substrate 110, an interposer through electrode 120, a redistribution structure 130, a conductive post 140, a chip connection terminal 150, an interposer insulating layer 160, an interposer connection pad 170, a passivation layer 180, and an interposer connection terminal 190.

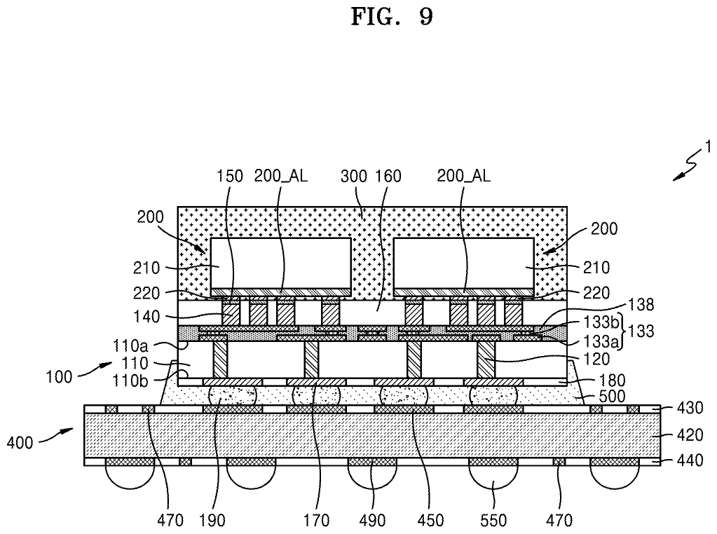

The interposer structure 100 may be a structure between a plurality of semiconductor chips 200 of FIG. 9 and a package substrate 400 of FIG. 9 and configured to electrically connect the plurality of semiconductor chips 200 to each other or electrically connect the plurality of semiconductor chips 200 and the package substrate 400 to each other.

The interposer substrate 110 may include a top surface 110a facing the redistribution structure 130 and a bottom surface 110b facing the interposer connection pad 170. Hereinafter, a direction parallel to a direction in which the top surface 110a and bottom surface 110b of the interposer substrate 110 are extending may be defined as a horizontal direction, and a direction perpendicular to the direction in which the top surface 110a and bottom surface 110b of the interposer substrate 110 are extending may be defined as a vertical direction.

According to an embodiment, a material of the interposer substrate 110 may include silicon (Si). However, the material is not limited thereto, and the interposer substrate 110 may include a semiconductor element such as germanium, or may include a semiconductor compound such as silicon carbide (SiC), gallium arsenide (GaAs), indium arsenide (InAs), or indium phosphide (InP).

The interposer through electrode 120 may penetrate through the interposer substrate 110 in the vertical direction. According to an embodiment, one surface of the interposer through electrode 120 may be electrically connected to a redistribution pattern 133 of the redistribution structure 130, and the other surface of the interposer through electrode 120 may be electrically connected to the interposer connection pad 170.

According to an embodiment, the interposer through electrode 120 may include a conductive plug (not shown) and a conductive barrier layer (not shown). The conductive plug may penetrate through at least a portion of the interposer substrate 110 in the vertical direction, and the conductive barrier layer may be on side walls of the conductive plug. For example, the conductive plug may have a cylindrical shape, and the conductive barrier layer may have a cylindrical shape on the side walls of the conductive plug.

The redistribution structure 130 may be on the interposer substrate 110. Also, the redistribution structure 130 may include a redistribution insulating layer 138 on the interposer substrate 110, and the redistribution pattern 133 extending into the redistribution insulating layer 138 and connected to the interposer through electrode 120.

According to an embodiment, the redistribution pattern 133 may include a redistribution line pattern 133a and a redistribution via pattern 133b. The redistribution line pattern 133a may be a pattern of a conductive material extending in the horizontal direction inside the redistribution insulating layer 138, and the redistribution via pattern 133b may be a pattern of a conductive material extending in the vertical direction inside the redistribution insulating layer 138.

A material of the redistribution insulating layer 138 may include an oxide or a nitride. For example, the material of the redistribution insulating layer 138 may include a silicon oxide or a silicon nitride. Also, the material of the redistribution insulating layer 138 may include photo imageable dielectric (PID) or photosensitive polyimide (PSPI). However, the material of the redistribution insulating layer 138 is not limited thereto.

According to an embodiment, a material of the redistribution pattern 133 may include copper (Cu). However, the material is not limited thereto, and the material of the redistribution pattern 133 may include a metal, such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The conductive post 140 may be on the redistribution structure 130, and may be a post of a conductive material extending in the vertical direction. According to an embodiment, the conductive post 140 may be on the redistribution structure 130 and electrically connected to the redistribution pattern 133. For example, one surface of the conductive post 140 may contact the redistribution line pattern 133a.

According to an embodiment, a material of the conductive post 140 may include at least one of Cu and Ni. However, the material is not limited thereto, and the material of the conductive post 140 may include at least one of Au, Ag, Al, W, Ti, Ta, In, Mo, Mn, Co, Sn, Mg, Re, Be, Ga, and Ru.

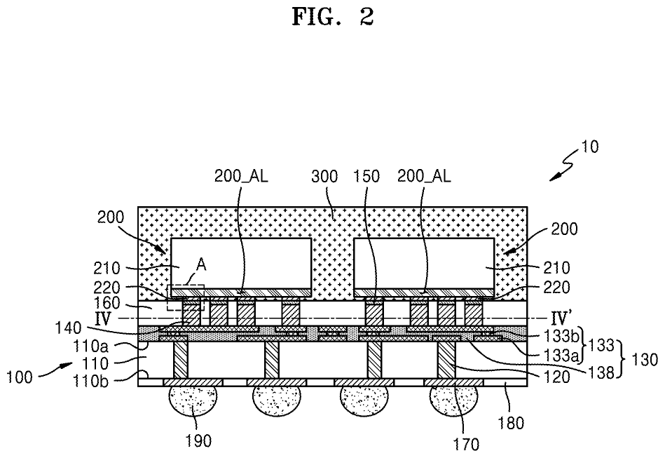

The chip connection terminal 150 may be a terminal on the conductive post 140 and configured to connect a chip pad 220 of the semiconductor chip 200 of FIG. 2 described below to the conductive post 140.

According to an embodiment, a material of the chip connection terminal 150 may include Sn. However, the material is not limited thereto, and the material of the chip connection terminal 150 may include at least one of Ag, Cu, and Al.

According to an embodiment, a sum of a length of the conductive post 140 in the vertical direction and a length of the chip connection terminal 150 in the vertical direction may be about 10 micrometers to about 50 micrometers. However, the sum of the length of the conductive post 140 in the vertical direction and the length of the chip connection terminal 150 in the vertical direction is not limited thereto.

According to an embodiment, a top surface of the chip connection terminal 150 may be exposed from a top surface of the interposer insulating layer 160 described below. For example, the top surface of the chip connection terminal 150 may be on a same plane as or coplanar with as the top surface of the interposer insulating layer 160.

The interposer insulating layer 160 may be on the redistribution structure 130 and on side surfaces of the conductive post 140 and the chip connection terminal 150. In detail, the interposer insulating layer 160 may be on a side surface of the conductive post 140 and a side surface of the chip connection terminal 150, and not on the top surface of the chip connection terminal 150.

According to an embodiment, a material of the interposer insulating layer 160 may include polyimide (PI). However, the material is not limited thereto, and the interposer insulating layer 160 may include various types of insulating materials.

The interposer connection pad 170 may be a pad of a conductive material on a lower portion such as the bottom surface 110b of the interposer substrate 110 and connected to the interposer through electrode 120. According to an embodiment, the material of the interposer connection pad 170 may include at least one of Ni, Cu, Au, Ag, W, Ti, Ta, In, Mo, Mn, Co, Sn, Mg, Re, Be, Ga, and Ru.

The passivation layer 180 may be on a lower portion such as the bottom surface 110b of the interposer substrate 110 and on at least a portion of a side surface of the interposer connection pad 170. Also, the passivation layer 180 may not be on a bottom surface of the interposer connection pad 170.

According to an embodiment, a material of the passivation layer 180 may include silicon oxynitride (SiON), silicon oxide (SiO₂), silicon oxycarbonitride (SiOCN), silicon carbonitride (SiCN), or a combination thereof.

The interposer connection terminal 190 may be a terminal of a conductive material on the interposer connection pad 170. In detail, the interposer connection terminal 190 may be a terminal of a conductive material electrically connecting the interposer structure 100 of the inventive concept to the package substrate 400 of FIG. 9.

According to an embodiment, the interposer connection terminal 190 may be a solder ball of a conductive material including at least one of Sn, Ag, Cu, and Al.

The interposer structure 100 according to an embodiment of the inventive concept includes the conductive post 140 on the redistribution structure 130 and connected to the redistribution pattern 133, the chip connection terminal 150 on the conductive post 140, and the interposer insulating layer 160 on the redistribution structure 130 and on side surfaces of the conductive post 140 and the chip connection terminal 150, and thus an electric connection between the plurality of semiconductor chips 200 of FIG. 2 and the interposer structure 100 may be facilitated during a thermal compression bonding process of mounting the plurality of semiconductor chips 200 on the interposer structure 100. For example, the electric connection between the plurality of semiconductor chips 200 having different sizes and the interposer structure 100 may be facilitated.

In addition, the interposer insulating layer 160 may support at least a portion of the plurality of semiconductor chips 200 during the thermal compression bonding process of mounting the plurality of semiconductor chips 200 of FIG. 2 on the interposer structure 100, and thus the plurality of semiconductor chips 200 may be prevented from tilting. Accordingly, structural reliability of a semiconductor package including the interposer structure 100 may be improved.

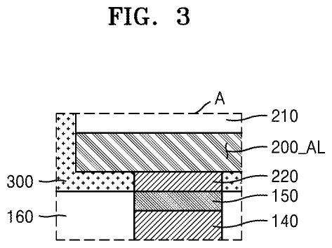

FIG. 2 is a cross-sectional view of a semiconductor package 10 according to an embodiment of the inventive concept. FIG. 3 is an enlarged view of a region A in FIG. 2.

Referring to FIGS. 2 and 3, the semiconductor package 10 according to an embodiment of the inventive concept may include the interposer structure 100, the semiconductor chips 200, and a molding layer 300.

Details about the interposer structure 100 are substantially the same as those described with reference to FIG. 1, and thus detailed descriptions thereof are omitted.

The semiconductor chip 200 may be mounted on the interposer structure 100. Also, a plurality of the semiconductor chips 200 may be on the interposer structure 100. According to an embodiment, the semiconductor chip 200 may include a semiconductor substrate 210 having an active layer 200_AL, and the chip pad 220 on a bottom surface of the semiconductor substrate 210.

According to an embodiment, the semiconductor chip 200 may include a memory semiconductor chip. For example, the memory semiconductor chip may include a volatile memory semiconductor chip, such as dynamic random-access memory (DRAM) or static random-access memory (SRAM), or may include a nonvolatile memory semiconductor chip, such as phase-change random access memory (PRAM), magneto-resistive random-access memory (MRAM), ferroelectric random-access memory (FeRAM), or resistive random-access memory (RRAM).

However, embodiments according to the inventive concept are not limited thereto, and the semiconductor chip 200 may include a logic semiconductor chip. For example, the logic semiconductor chip may include a central processor unit (CPU), a microprocessor unit (MPU), a graphics processor unit (GPU), or an application processor (AP).

According to an embodiment, when the plurality of semiconductor chips 200 are provided, the plurality of semiconductor chips 200 may be different types of semiconductor chips. In this case, the semiconductor package 10 may be a system-in-package (SIP), in which the plurality of semiconductor chips 200 are electrically connected to each other to operate as one system. However, an embodiment is not limited thereto, and the plurality of semiconductor chips 200 may be a same type of semiconductor chips.

A material of the semiconductor substrate 210 of the semiconductor chip 200 may include Si. Also, the material of the semiconductor substrate 210 may include a semiconductor element such as GE, or a compound semiconductor such as SiC, GaAs, InAs, or InP. However, the material of the semiconductor substrate 210 is not limited thereto.

According to an embodiment, the semiconductor substrate 210 may include the active layer 200_AL therebelow. The active layer 200_AL may include various types of a plurality of individual devices. For example, the plurality of individual devices may include various micro electronic devices, such as a complementary metal-oxide semiconductor (CMOS) transistor, a metal-oxide-semiconductor field effect transistor (MOSFET), a system large scale integration (LSI), an image sensor such as a CMOS imaging sensor (CIS), a micro-electro-mechanical system (MEMS), an active device, and a passive device.

The chip pad 220 of the semiconductor chip 200 may be a pad of a conductive material provided on a bottom surface of the semiconductor substrate 210 and electrically connected to the plurality of individual devices in the active layer 200_AL.

According to an embodiment, a material of the chip pad 220 may include at least one of Cu, Ni, and Au. However, the material is not limited thereto, and the material of the chip pad 220 may include at least one of Ag, Al, W, Ti, Ta, In, Mo, Mn, Co, Sn, Mg, Re, Be, Ga, and Ru.

According to an embodiment, a length of the chip pad 220 in the vertical direction may be about 1 micrometer to about 5 micrometers. However, the length of the chip pad 220 in the vertical direction is not limited thereto.

According to an embodiment, when the semiconductor package 10 includes the plurality of semiconductor chips 200, the lengths of the chip pads 220 in the vertical direction included in the plurality of semiconductor chips 200 may be different from each other. However, an embodiment is not limited thereto, and the lengths of the chip pads 220 in the vertical direction included in the plurality of semiconductor chips 200 may be substantially the same.

According to an embodiment, the chip pad 220 of the semiconductor chip 200 may contact the chip connection terminal 150 of the interposer structure 100. Accordingly, the semiconductor chip 200 may be electrically connected to the interposer structure 100 through the chip pad 220.

According to an embodiment, a top surface of the interposer insulating layer 160 of the interposer structure 100 and a top surface of the chip connection terminal 150 may be on a same plane. Accordingly, when the semiconductor chip 200 is mounted on the interposer structure 100, a bottom surface of the semiconductor substrate 210 may be provided at a higher level than the top surface of the interposer insulating layer 160. That is, the bottom surface of the semiconductor substrate 210 and the top surface of the interposer insulating layer 160 are spaced apart in the vertical direction.

In other words, a space between the bottom surface of the semiconductor substrate 210 and the top surface of the interposer insulating layer 160 may be formed by the chip pad 220 of the semiconductor chip 200, and the molding layer 300 described below may fill the space.

The molding layer 300 may be provided on the interposer structure 100 and contact side surfaces of the semiconductor chip 200. According to an embodiment, the molding layer 300 may include an epoxy molding compound (EMC). However, a material of the molding layer 300 is not limited thereto.

According to an embodiment, a side surface of the molding layer 300 and a side surface of the interposer structure 100 may be on a same plane. For example, the side surface of the molding layer 300, a side surface of the interposer insulating layer 160, a side surface of the redistribution structure 130, and a side surface of the interposer substrate 110 may be provided on a same plane.

The semiconductor package 10 according to an embodiment of the inventive concept includes the interposer structure 100 described above, and thus an electric connection between the plurality of semiconductor chips 200 and the interposer structure 100 may be facilitated during a process of mounting the plurality of semiconductor chips 200 on the interposer structure 100.

Also, during the process of mounting the plurality of semiconductor chips 200 on the interposer structure 100 of the semiconductor package 10, the interposer insulating layer 160 of the interposer structure 100 is able to support the plurality of semiconductor chips 200, and thus the plurality of semiconductor chips 200 may be prevented from tilting. Accordingly, structural reliability of the semiconductor package 10 including the interposer structure 100 may be improved.

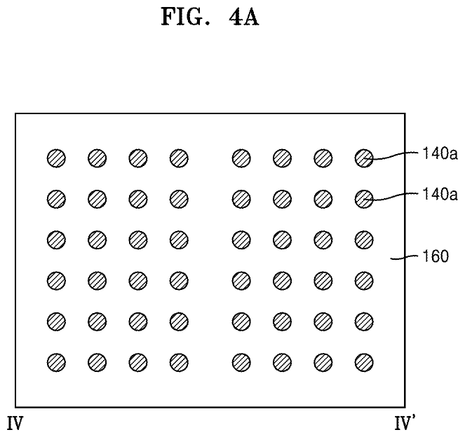

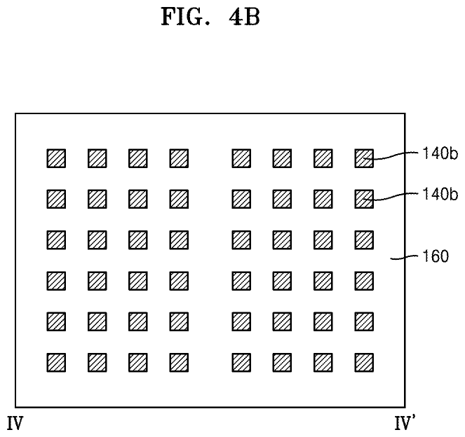

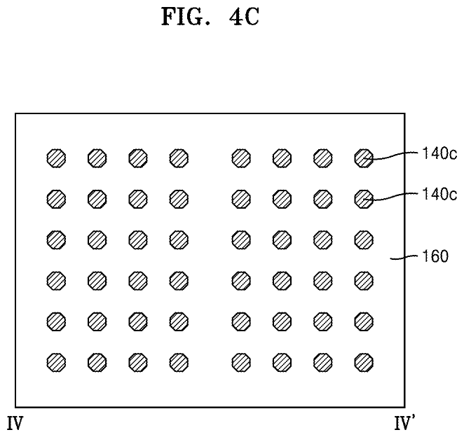

FIGS. 4A through 4C are cross-sectional views taken along a line IV-IV′ of FIG. 2.

Referring to FIGS. 4A through 4C, each of first through third conductive posts 140a through 140c of the semiconductor package 10, according to an embodiment of the inventive concept, may be arranged in a form of M×N matrix including M rows that is an integer of 2 or greater and N columns that is an integer of 2 or greater.

However, an embodiment is not limited thereto, and each of the first through third conductive posts 140a through 140c may be arranged in a zigzag structure or a honeycomb structure.

Referring to FIG. 4A, a cross-section of the first conductive post 140a in the horizontal direction may be a circular shape. In other words, the first conductive post 140a may have a cylindrical shape.

Referring to FIG. 4B, a cross-section of the second conductive post 140b in the horizontal direction may be a rectangular shape. In other words, the second conductive post 140b may have a rectangular column shape.

Referring to FIG. 4C, a cross-section of the third conductive post 140c in the horizontal direction may be an octagonal shape. In other words, the third conductive post 140c may have an octagonal column shape.

However, an embodiment is not limited thereto, and the cross-section of each of the first through third conductive posts 140a through 140c in the horizontal direction may be a polygonal shape, such as a triangular shape, a pentagonal shape, and a hexagonal shape. In other words, each of the first through third conductive posts 140a through 140c may have a polygonal column shape.

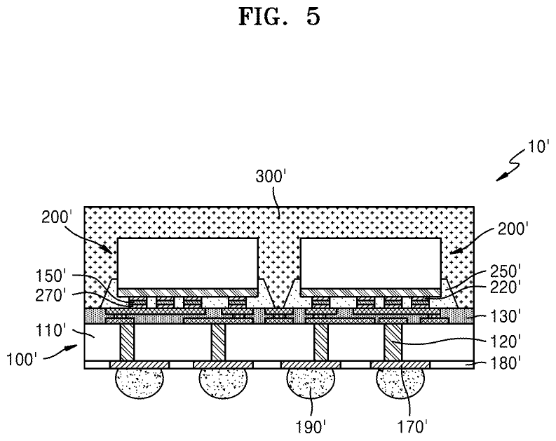

FIG. 5 is a cross-sectional view of a semiconductor package 10′ according to a comparative example.

The semiconductor package 10′ according to the comparative example may include an interposer structure 100′, a semiconductor chip 200′, an underfill layer 250′, and a molding layer 300′. Also, the interposer structure 100′ may include an interposer substrate 110′, an interposer penetration electrode 120′, a redistribution structure 130′, a chip connection pad 150′, an interposer connection pad 170′, a passivation layer 180′, and an interposer connection terminal 190′.

The semiconductor chip 200′ may be electrically connected to the interposer structure 100′ by a chip connection terminal 270′ provided between a bottom surface of a chip pad 220′ and the chip connection pad 150′ of the interposer structure 100′.

During a thermal compression bonding process of mounting the semiconductor chip 200′ on the interposer structure 100′, a warpage of the semiconductor package 10′ may occur due to a difference of coefficients of thermal expansion (CTE) between a semiconductor substrate 210′ of the semiconductor chip 200′ and the interposer substrate 110′ of the interposer structure 100′. When the warpage of the semiconductor package 10′ occurs, a bonding defect between the semiconductor chip 200′ and the interposer structure 100′ may occur.

When the plurality of semiconductor chips 200′ are mounted on the interposer structure 100′, a process of forming the underfill layer 250′ in a space between the plurality of semiconductor chips 200′ and the interposer structure 100′ needs to be performed a plurality of times.

The semiconductor package 10 of FIG. 2 according to an embodiment of the inventive concept includes the interposer insulating layer 160 provided between the semiconductor substrate 210 and the interposer substrate 110, and thus a warpage of the semiconductor package 10 caused by a difference of CTE between the semiconductor substrate 210 and the interposer substrate 110 may be improved. Accordingly, a bonding defect of the semiconductor package 10 may be improved and structural reliability thereof may be improved.

Also, a process of forming an underfill layer in each of the spaces between the plurality of semiconductor chips 200 and the interposer structure 100 may be omitted during the process of mounting the plurality of semiconductor chips 200 on the interposer structure 100 of the semiconductor package 10 of the inventive concept. Accordingly, a time of a method of manufacturing the semiconductor package 10 of the inventive concept may be reduced.

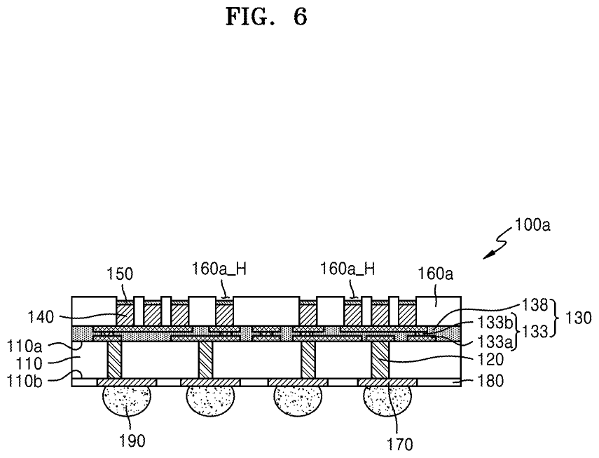

FIG. 6 is a cross-sectional view of an interposer structure 100a according to an embodiment of the inventive concept.

Referring to FIG. 6, the interposer structure 100a according to an embodiment of the inventive concept may include the interposer substrate 110, the interposer through electrode 120, the redistribution structure 130, the conductive post 140, the chip connection terminal 150, an interposer insulating layer 160a, the interposer connection pad 170, the passivation layer 180, and the interposer connection terminal 190.

Hereinafter, overlapping details of the interposer structure 100 of FIG. 1 and the interposer structure 100a of FIG. 6 are omitted and differences thereof are mainly described.

The interposer insulating layer 160a may include an insulating hole 160a_H exposing at least a portion of the chip connection terminal 150. According to an embodiment, the insulating hole 160a_H may overlap the chip connection terminal 150 and the conductive post 140 in the vertical direction. Also, the insulating hole 160a_H may provide a space where a semiconductor chip 200a and a chip pad 220a described below are arranged.

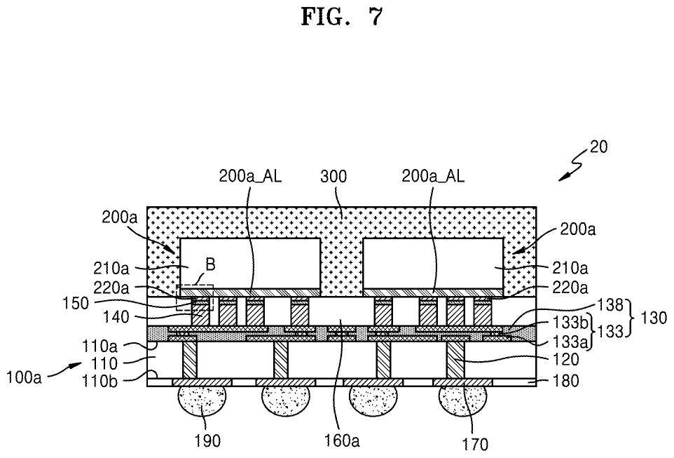

Also, a depth of the insulating hole 160a_H (i.e., a length of the insulating hole 160a_H in the vertical direction) may be substantially the same as a length of the chip pad 220a of the semiconductor chip 200a of FIG. 7 in the vertical direction.

According to an embodiment, a length of the interposer insulating layer 160a in the vertical direction may be greater than a sum of the length of the conductive post 140 in the vertical direction and the length of the chip connection terminal 150 in the vertical direction. Accordingly, the interposer insulating layer 160a may be on the side surface of the conductive post 140 and the side surface of the chip connection terminal 150.

According to an embodiment, a level of a top surface of the interposer insulating layer 160a may be higher than a level of the top surface of the chip connection terminal 150.

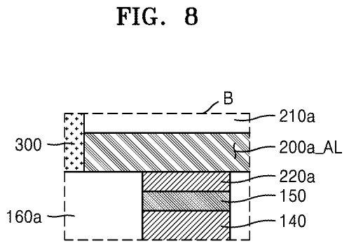

FIG. 7 is a cross-sectional view of a semiconductor package 20 according to an embodiment of the inventive concept. Also, FIG. 8 is an enlarged view of a region B in FIG. 7.

Referring to FIGS. 7 and 8 together, the semiconductor package 20 according to an embodiment of the inventive concept may include the interposer structure 100a, the semiconductor chips 200a, and the molding layer 300.

Hereinafter, overlapping details of the semiconductor package 10 of FIGS. 2 and 3 and the semiconductor package 20 of FIGS. 7 and 8 are omitted, and differences thereof are mainly described.

According to an embodiment, the chip pad 220a of the semiconductor chip 200a may be provided in the insulating hole 160a_H of the interposer insulating layer 160a described with reference to FIG. 6, and contact the chip connection terminal 150.

Also, the interposer structure 100a may support a lower portion of the semiconductor chip 200a. In detail, a top surface of the interposer insulating layer 160a of the interposer structure 100a may support a bottom surface of a semiconductor substrate 210a of the semiconductor chip 200a. The interposer insulating layer 160a is able to support the semiconductor chip 200a, and thus structural reliability of the semiconductor package 20 may be improved.

According to an embodiment, the level of the top surface of the interposer insulating layer 160a may be higher than the level of the top surface of the chip connection terminal 150. Also, the top surface of the interposer insulating layer 160a and the bottom surface of the semiconductor substrate 210a may be provided on a same plane.

The chip pad 220a of the semiconductor chip 200a according to an embodiment of the inventive concept is provided in the insulating hole 160a_H of the interposer insulating layer 160a, and the top surface of the interposer insulating layer 160a is able to contact the bottom surface of the semiconductor substrate 210a, and thus the size of the semiconductor package 20 according to the inventive concept may be decreased. For example, a length of the semiconductor package 20 in the vertical direction may be decreased.

FIG. 9 is a cross-sectional view of a semiconductor package 1 according to an embodiment of the inventive concept.

Referring to FIG. 9, the semiconductor package 1 according to an embodiment of the inventive concept may include the interposer structure 100, the semiconductor chip 200, the molding layer 300, the package substrate 400, an underfill layer 500, an external connection terminal 550, and the like. Details about the interposer structure 100, the semiconductor chip 200, and the molding layer 300 of FIG. 9 overlap those described with reference to FIGS. 2 and 3, and thus detailed descriptions thereof are omitted.

The package substrate 400 may be a substrate supporting the interposer structure 100. Also, the package substrate 400 may include a baseboard layer 420, an upper solder resist layer 430, a lower solder resist layer 440, a package substrate pad 450, a substrate line pattern 470, an external connection pad 490, and the like.

According to an embodiment, the package substrate 400 may be a printed circuit board (PCB). However, the package substrate 400 is not limited by a structure and material of the PCB, and may include any type of substrates, such as a ceramic substrate.

The baseboard layer 420 may be formed of at least one material selected from among phenol resin, epoxy resin, and polyimide. For example, the baseboard layer 420 may include at least one material selected from among flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

According to an embodiment, the baseboard layer 420 may include polyester, polyester terephthalate, fluorinated ethylene propylene (FEP), resin-coated paper, liquid polyimide resin, a polyethylene naphthalate (PEN) film, or the like.

According to an embodiment, the upper solder resist layer 430 may be provided at an upper portion of the baseboard layer 420 and on side portions of the substrate line pattern 470 and package substrate pad 450. Also, the upper solder resist layer 430 may expose at least a portion of the package substrate pad 450.

According to an embodiment, the lower solder resist layer 440 may be provided at a lower portion of the baseboard layer 420 and on side portions of the substrate line pattern 470 and external connection pad 490. Also, the lower solder resist layer 440 may expose at least a portion of the external connection pad 490.

According to an embodiment, the upper solder resist layer 430 and the lower solder resist layer 440 may include a polyimide film, a polyester film, a flexible solder mask, a photo-imageable coverlay (PIC), or photo-imageable solder resist.

For example, the upper solder resist layer 430 and the lower solder resist layer 440 may be formed by thermally curing thermosetting ink coated via a silk screen printing method or an inkjet method. Also, the upper solder resist layer 430 and the lower solder resist layer 440 may be formed by removing, via exposure and developing, a portion of photo-imageable solder resist coated via a screen method or a spray coating method, and then thermally curing the photo-imageable solder resist.

The substrate line pattern 470 may extend in the horizontal direction at the upper and lower portions of the baseboard layer 420, and be electrically connected to the package substrate pad 450 and the external connection pad 490. Also, the substrate line pattern 470 may be covered by the upper solder resist layer 430 and the lower solder resist layer 440.

According to an embodiment, a material of the substrate line pattern 470 may include Cu. For example, the material of the substrate line pattern 470 may include at least one of electrolytically deposited copper, rolled-annealed copper foil, stainless steel foil, aluminum foil, ultra-thin copper foil, sputtered copper, a copper alloy, nickel, stainless steel, and beryllium copper.

The package substrate pad 450 may be provided at the upper portion of the baseboard layer 420 and electrically connected to the substrate line pattern 470. Also, at least a portion of the package substrate pad 450 may be exposed by the upper solder resist layer 430, and the exposed portion of the package substrate pad 450 may contact the interposer connection terminal 190.

The external connection pad 490 may be provided at the lower portion of the baseboard layer 420 and electrically connected to the substrate line pattern 470. Also, at least a portion of the external connection pad 490 may be exposed by the lower solder resist layer 440, and the exposed portion of the external connection pad 490 may contact the external connection terminal 550.

The underfill layer 500 may be between the package substrate 400 and the interposer structure 100, and on side surfaces of the interposer connection terminal 190. In other words, the underfill layer 500 may fix the interposer structure 100 to a top surface of the package substrate 400.

According to an embodiment, a material of the underfill layer 500 may include at least one of insulating polymer and epoxy resin. For example, the material of the underfill layer 500 may include an epoxy molding compound (EMC).

The external connection terminal 550 may be attached to the external connection pad 490. Also, the external connection terminal 550 may be a terminal configured to electrically connect the interposer structure 100 and the semiconductor chip 200 to an external device.

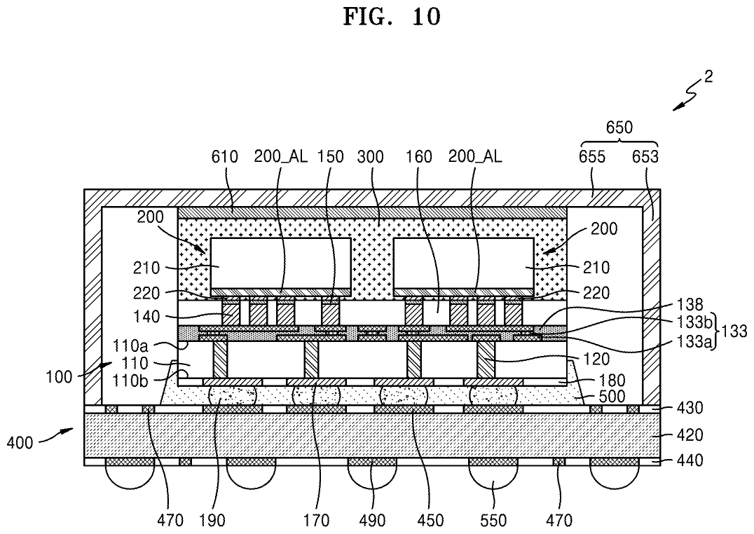

FIG. 10 is a cross-sectional view of a semiconductor package 2 according to an embodiment of the inventive concept.

Referring to FIG. 10, the semiconductor package 2 may further include an adhesive layer 610 and a heat sink 650.

The heat sink 650 may be a heat dissipating member configured to externally emit heat generated in the semiconductor chip 200. According to an embodiment, the heat sink 650 may be mounted on the package substrate 400 and on side portions of the molding layer 300, interposer structure 100, and underfill layer 500.

According to an embodiment, the heat sink 650 may include a first heat dissipating portion 653extending in the vertical direction from the top surface of the package substrate 400, and a second heat dissipating portion 655 extending in the horizontal direction from a top surface of the adhesive layer 610 and connected to the first heat dissipating portion 653.

According to an embodiment, the heat sink 650 may include at least one material from among a metal-based material, a ceramic-based material, a carbon-based material, and a polymer-based material. For example, the heat sink 650 may include a metal-based material, such as Al, Mg, Cu, Ni, and Ag.

The adhesive layer 610 may be on the molding layer 300 and configured to fix the heat sink 650 to an upper portion of the molding layer 300. For example, the adhesive layer 610 may include an adhesive film having a self-adhesive characteristic.

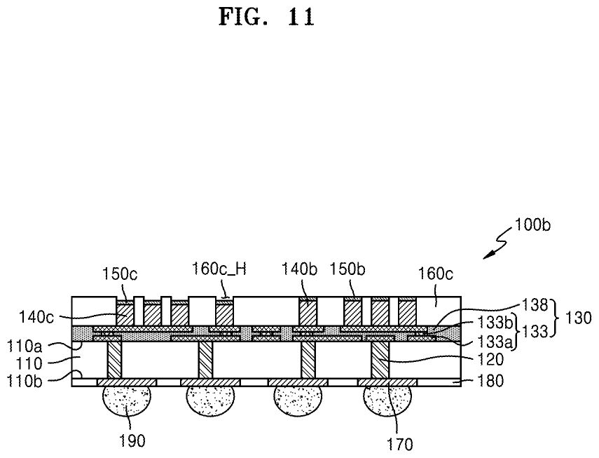

FIG. 11 is a cross-sectional view of an interposer structure 100b according to an embodiment of the inventive concept.

The interposer structure 100b according to an embodiment of the inventive concept may include the interposer substrate 110, the interposer through electrode 120, the redistribution structure 130, the first conductive post 140b, the second conductive post 140c, a first chip connection terminal 150b, a second chip connection terminal 150c, an interposer insulating layer 160c, the interposer connection pad 170, the passivation layer 180, and the interposer connection terminal 190.

Hereinafter, overlapping details of the interposer structure 100 of FIG. 1 and the interposer structure 100b of FIG. 11 are omitted and differences thereof are mainly described.

The first conductive post 140b may be on the interposer insulating layer 160c and have a first length in the vertical direction. Also, the second conductive post 140c may be on the interposer insulating layer 160c and have a second length less than the first length, in the vertical direction.

Also, the first chip connection terminal 150b may be on the first conductive post 140b, and the second chip connection terminal 150c may be on the second conductive post 140c.

According to an embodiment, a level of a top surface of the first chip connection terminal 150b may be substantially the same as a level of a top surface of the interposer insulating layer 160c. Also, a top surface of the second chip connection terminal 150c may be at a lower level than a top surface of the interposer insulating layer 160c. Thus, the top surface of the first chip connection terminal 150b and the top surface of the second chip connection terminal 150c are not coplanar. In other words, the interposer insulating layer 160c may include an insulating hole 160c_H exposing a portion of the second chip connection terminal 150c.

A level of the top surface of the first chip connection terminal 150b of the interposer structure 100b of the inventive concept and a level of the top surface of the second chip connection terminal 150c may be different from each other, and thus a plurality of semiconductor chips having different sizes may be mounted on the interposer structure 100b.

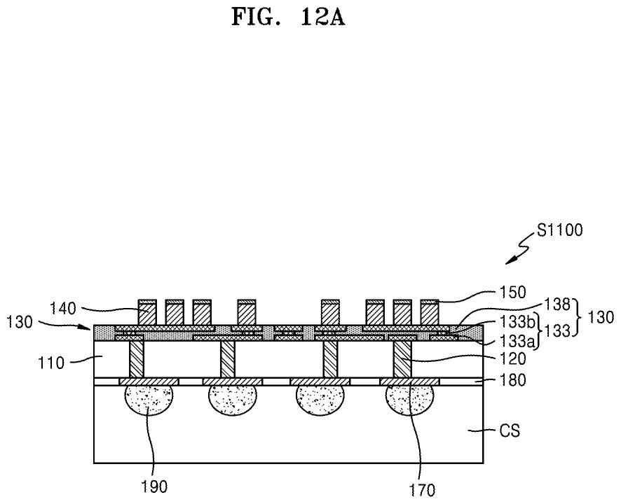

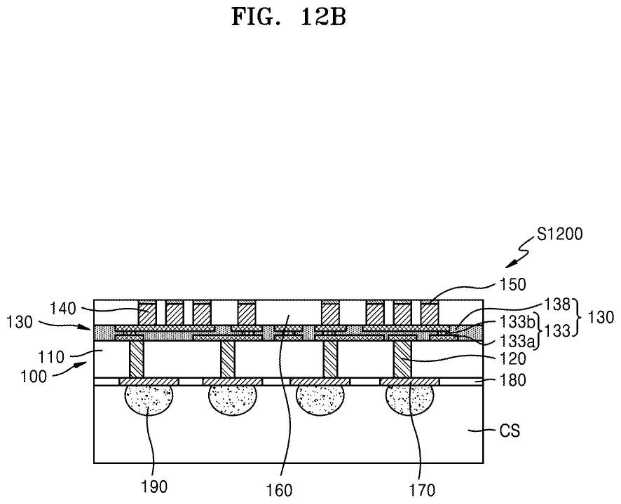

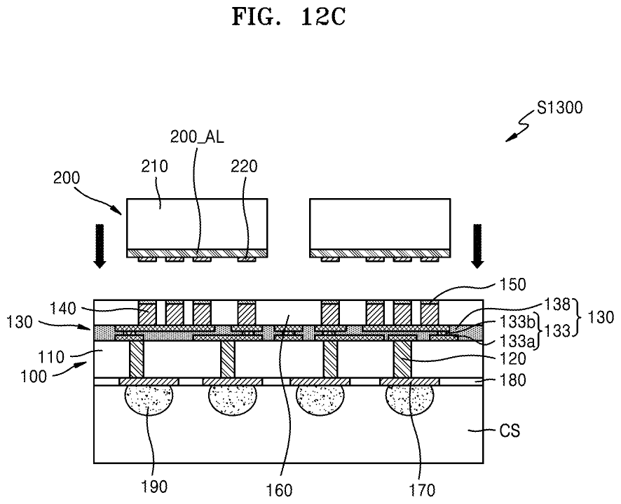

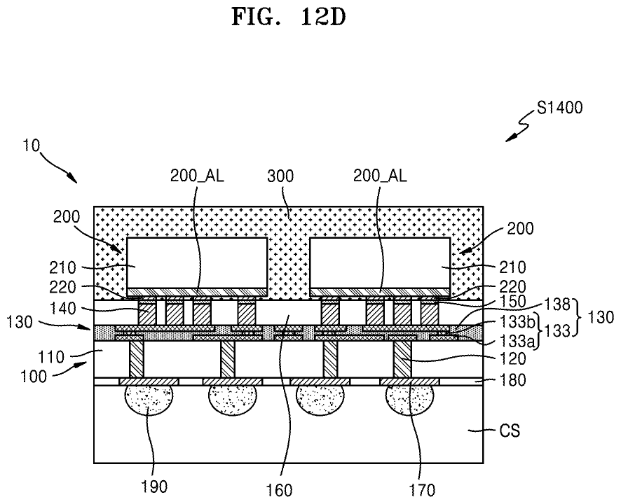

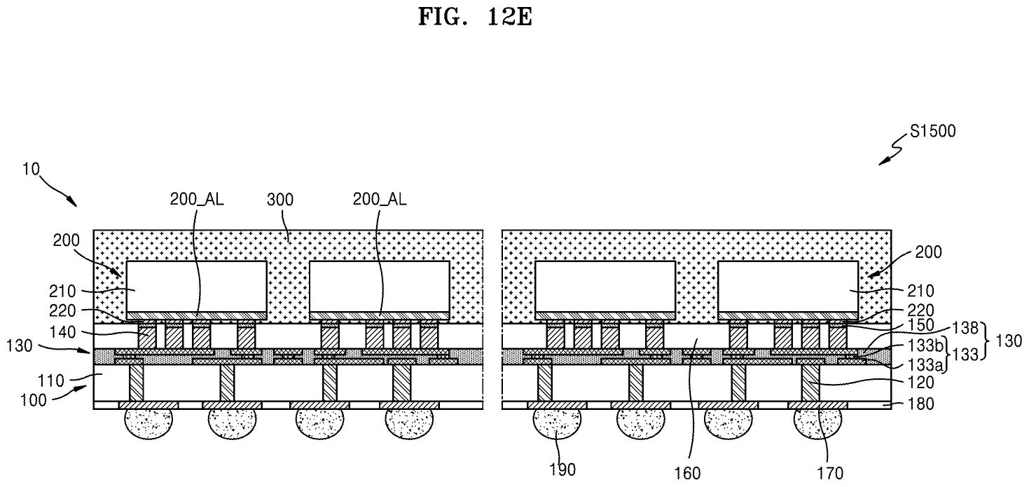

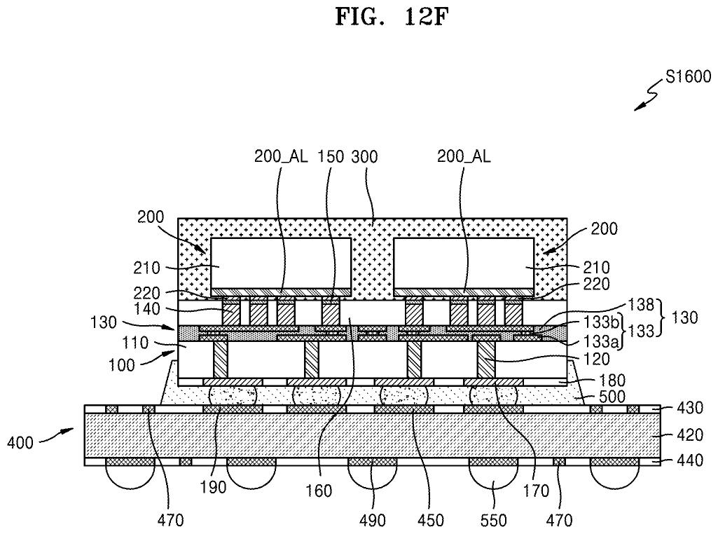

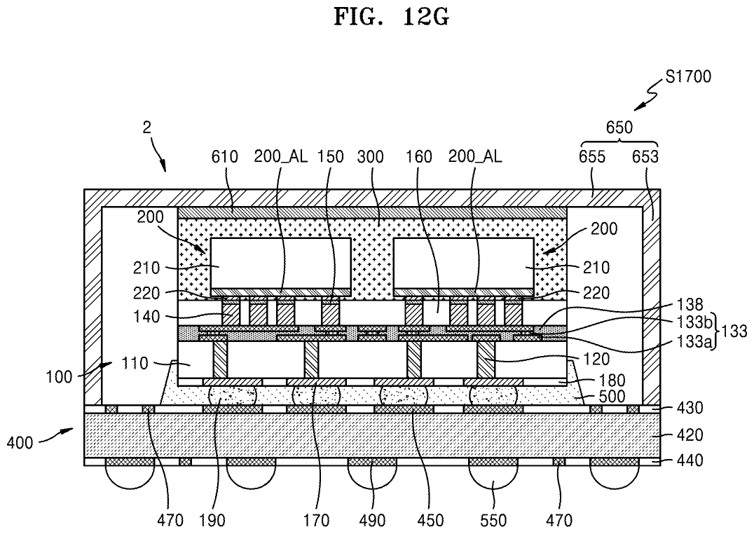

FIGS. 12A through 12G are views for describing operations of a method of manufacturing a semiconductor package, according to an embodiment of the inventive concept.

Hereinafter, the method of manufacturing a semiconductor package, according to an embodiment of the inventive concept, will be described in detail with reference to FIGS. 12A through 12G. The method of the inventive concept may be a method of manufacturing the semiconductor package 2 described with reference to FIG. 10.

Referring to FIG. 12A, the method according to an embodiment of the inventive concept may include forming the conductive post 140 and the chip connection terminal 150 on the redistribution structure 130 (operation S1100).

Before operation S1100 is performed, a carrier substrate CS may be attached to a lower portion of the interposer substrate 110. For example, the carrier substrate CS may be a substrate including an arbitrary material having stability during a semiconductor process, such as a baking process, an etching process, or the like.

According to an embodiment, when the carrier substrate CS is to be separated and removed via laser ablation, the carrier substrate CS may be a transparent substrate. Selectively, when the carrier substrate CS is to be separated and removed via heating, the carrier substrate CS may be a heat resistant substrate.

According to an embodiment, the carrier substrate CS may be a glass substrate. According to another embodiment, the carrier substrate CS may include a heat resistant organic polymer material, such as PI, polyetheretherketone (PEEK), polyethersulfone (PES), polyphenylene sulfide (PPS), or the like, but is not limited thereto.

According to an embodiment, a release film (not shown) may be attached to one surface of the carrier substrate CS. For example, the release film may be a laser reactive layer enabling the carrier substrate CS to be separated by being evaporated in response to irradiation of laser later. The release film may include a carbon-based material layer. For example, the release film may include an amorphous carbon layer (ACL).

Also, according to an embodiment, the interposer substrate 110 may be provided for each wafer level. Accordingly, operations S1100 through S1400 may be performed in a wafer level.

In operation S1100, the conductive post 140 may be mounted on the redistribution structure 130. For example, the conductive post 140 may be mounted on the redistribution structure 130 such that the conductive post 140 is connected to the redistribution line pattern 133a of the redistribution structure 130.

According to an embodiment, the material of the conductive post 140 may include at least one of Cu and Ni. However, the material of the conductive post 140 is not limited thereto.

Also, in operation S1100, the chip connection terminal 150 may be mounted on an upper portion of the conductive post 140. According to an embodiment, the material of the chip connection terminal 150 may include Sn. However, the material is not limited thereto, and the material of the chip connection terminal 150 may include at least one of Ag, Cu, and Al.

According to an embodiment, the sum of the length of the conductive post 140 in the vertical direction and the length of the chip connection terminal 150 in the vertical direction may be about 10 micrometers to about 50 micrometers.

Referring to FIG. 12B, the method according to an embodiment of the inventive concept may include forming the interposer insulating layer 160 on the redistribution structure 130 (operation S1200).

According to an embodiment, operation S1200 may include: forming the interposer insulating layer 160 on the redistribution structure 130 such as to cover the side surface of the conductive post 140, and the side and top surfaces of the chip connection terminal 150; and removing a portion of the interposer insulating layer 160 such that the top surface of the chip connection terminal 150 is exposed.

According to an embodiment, the material of the interposer insulating layer 160 may include PI. However, the material is not limited thereto, and the interposer insulating layer 160 may include various types of insulating materials.

According to an embodiment, after the interposer insulating layer 160 covers the side surface of the conductive post 140 and the side and top surfaces of the chip connection terminal 150 on the redistribution structure 130, a top portion of the interposer insulating layer 160 may be grinded such that the top surface of the chip connection terminal 150 is exposed.

By performing operation S1200, manufacturing of the interposer structure 100 described with reference to FIG. 1 may be completed.

Referring to FIG. 12C, the method according to an embodiment of the inventive concept may include mounting the semiconductor chip 200 on the interposer structure 100 (operation S1300).

In operation S1300, the semiconductor chip 200 may be mounted on the interposer insulating layer 160 of the interposer structure 100. According to an embodiment, the semiconductor chip 200 may be mounted on the interposer insulating layer 160 such that the chip pad 220 of the semiconductor chip 200 contacts the chip connection terminal 150 exposed by the interposer insulating layer 160.

According to an embodiment, in operation S1300, the chip pad 220 of the semiconductor chip 200 may be integrated with the chip connection terminal 150 of the interposer structure 100 via a thermal compression bonding process.

The interposer structure 100 of the inventive concept includes the interposer insulating layer 160 between the semiconductor substrate 210 of the semiconductor chip 200 and the interposer substrate 110 of the interposer structure 100, and thus a warpage of a structure of operation S1300 occurred due to a difference of CTE between the semiconductor substrate 210 and the interposer substrate 110 during the thermal compression bonding process of mounting the semiconductor chip 200 on the interposer structure 100 may be improved.

In addition, according to the method of the inventive concept, a process of forming an underfill layer in each of spaces between the plurality of semiconductor chips 200 and the interposer structure 100 may be omitted. Accordingly, a time of the method of manufacturing a semiconductor package of the inventive concept may be reduced.

Referring to FIG. 12D, the method according to an embodiment of the inventive concept may include forming the molding layer 300 on the interposer insulating layer 160 (operation S1400).

According to an embodiment, in operation S1400, the molding layer 300 may be at the upper portion of the interposer insulating layer 160 and cover the side and top surfaces of the semiconductor chip 200. However, an embodiment is not limited thereto, and the molding layer 300 may be at the upper portion of the interposer insulating layer 160, cover the side surface of the semiconductor chip 200, and expose the top surface of the semiconductor chip 200.

Referring to FIG. 12E, the method according to an embodiment of the inventive concept may include individualizing the structure of operation S1400 (operation S1500).

The carrier substrate CS may be removed before operation S1500 is performed. For example, the carrier substrate CS may be removed via laser ablation or heating.

In operation S1500, the structure of operation S1400 manufactured in a wafer level may be individualized. In detail, in operation S1500, a scribe lane formed in the structure of operation S1400 may be cut. For example, the scribe lane of the structure of operation S1400 may be physically removed by a dicing blade (not shown). Accordingly, the semiconductor package 10 described with reference to FIG. 2 may be manufactured.

Referring to FIG. 12F, the method according to an embodiment of the inventive concept may include mounting the individualized structure of operation S1500 on the package substrate 400 (operation S1600).

According to an embodiment, in operation S1600, the individualized structure of operation S1500 may be mounted on the package substrate 400. For example, the individualized structure of operation S1500 may be mounted on the package substrate 400 such that the interposer connection terminal 190 of the interposer structure 100 contacts the package substrate pad 450 of the package substrate 400.

Also, in operation S1600, the underfill layer 500 may be formed between the package substrate 400 and the interposer structure 100. For example, an underfill material may be injected into the space between the package substrate 400 and the interposer structure 100.

According to an embodiment, the underfill layer 500 may be between the package substrate 400 and the interposer structure 100, and on the side portion of the interposer connection terminal 190.

Referring to FIG. 12G, the method according to an embodiment of the inventive concept may include forming the heat sink 650 and the external connection terminal 550 (operation S1700).

According to an embodiment, in operation S1700, the heat sink 650 may be on the package substrate 400 and on the molding layer 300 and the interposer structure 100. Also, the heat sink 650 may be fixed to the upper portion of the molding layer 300 by the adhesive layer 610.

According to an embodiment, in operation S1700, the external connection terminal 550 may be attached to the external connection pad 490 of the package substrate 400.

By performing operations S1100 through S1700, manufacturing of the semiconductor package 2 according to an embodiment of the inventive concept may be completed.

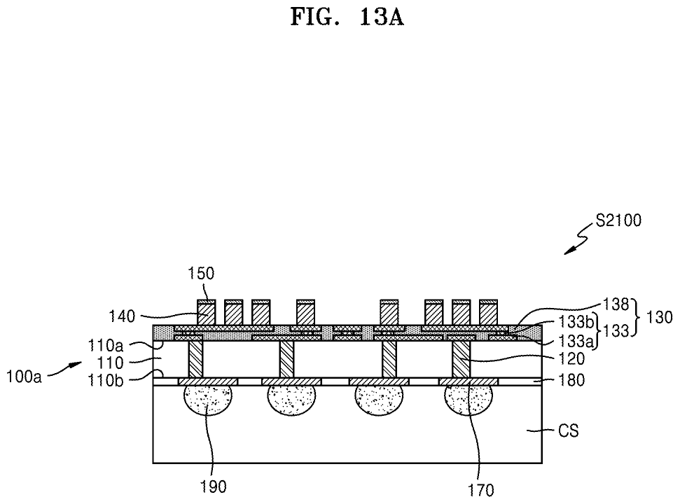

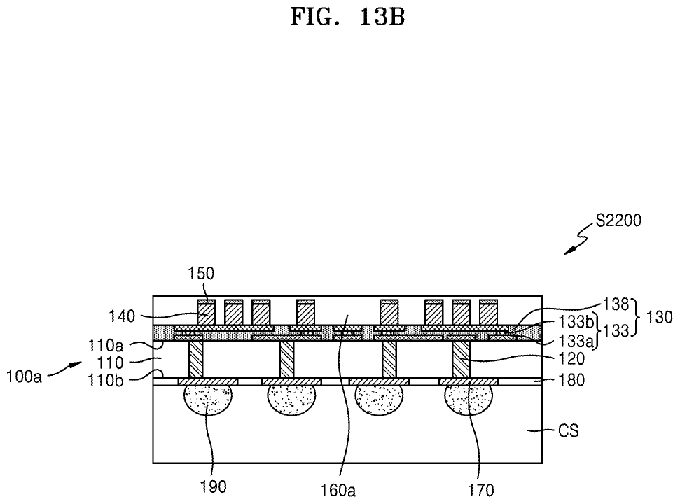

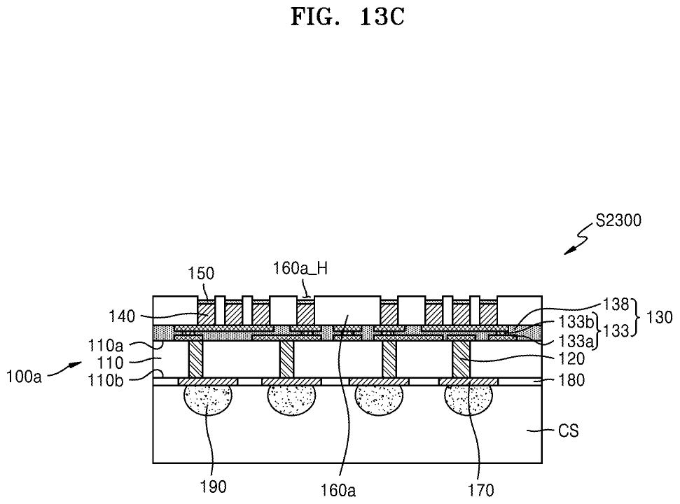

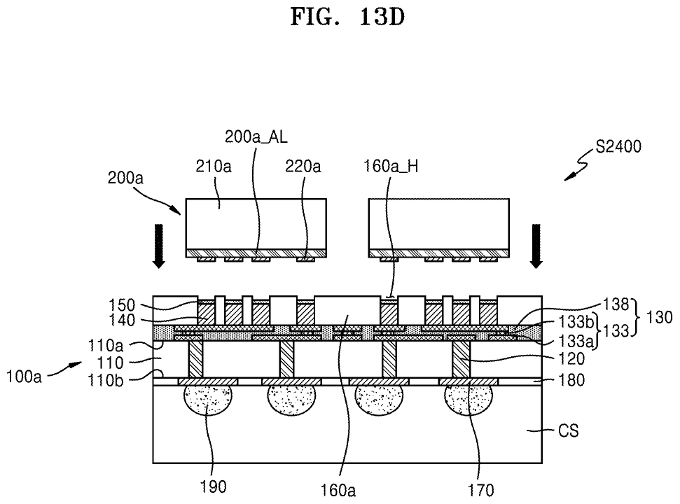

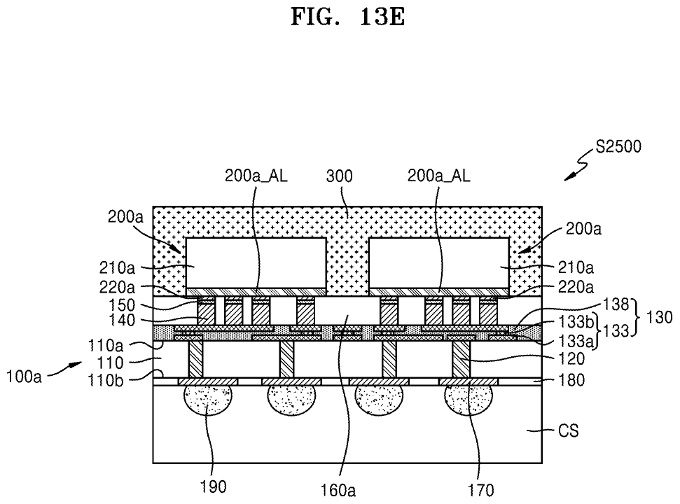

FIGS. 13A through 13E are views for describing operations of a method of manufacturing a semiconductor package, according to an embodiment of the inventive concept. In detail, the method according to an embodiment of the inventive concept may be a method of manufacturing the semiconductor package 20 described with reference to FIG. 7.

Referring to FIG. 13A, the method according to an embodiment of the inventive concept may include forming the conductive post 140 and the chip connection terminal 150 on the redistribution structure 130 (operation S2100).

Before operation S2100 is performed, the carrier substrate CS may be attached to the lower portion of the interposer substrate 110. For example, the carrier substrate CS may be a substrate including an arbitrary material having stability during a semiconductor process, such as a baking process, an etching process, or the like.

Also, according to an embodiment, the interposer substrate 110 may be provided for each wafer level. Accordingly, operations S2100 through S2400 may be performed in a wafer level.

In operation S2100, the conductive post 140 may be mounted on the redistribution structure 130. For example, the conductive post 140 may be mounted on the redistribution structure 130 such that the conductive post 140 is connected to the redistribution line pattern 133a of the redistribution structure 130.

Also, in operation S2100, the chip connection terminal 150 may be mounted on the upper portion of the conductive post 140. According to an embodiment, the material of the chip connection terminal 150 may include Sn. However, the material is not limited thereto, and the material of the chip connection terminal 150 may include at least one of Ag, Cu, and Al.

Referring to FIG. 13B, the method according to an embodiment of the inventive concept may include forming the interposer insulating layer 160a on the redistribution structure 130 (operation S2200).

According to an embodiment, operation S2200 may include forming the interposer insulating layer 160a on the redistribution structure 130 such as to cover the side surface of the conductive post 140, and the side and top surfaces of the chip connection terminal 150.

According to an embodiment, the material of the interposer insulating layer 160a may include PI. However, the material is not limited thereto, and the interposer insulating layer 160a may include various types of insulating materials.

Referring to FIG. 13C, the method according to an embodiment of the inventive concept may include removing at least a portion of the interposer insulating layer 160a such that the chip connection terminal 150 is exposed (operation S2300).

In operation S2300, a portion of the interposer insulating layer 160a, which overlap the chip connection terminal 150 in the vertical direction, may be removed. In other words, the interposer insulating layer 160a may include the insulating hole 160a_H exposing the top surface of the chip connection terminal 150.

For example, the insulating hole 160a_H of the interposer insulating layer 160a may be formed through a photolithography process, an etching process, and the like. However, a method of forming the insulating hole 160a_H of the interposer insulating layer 160a is not limited thereto.

Referring to FIG. 13D, the method according to an embodiment of the inventive concept may include mounting the semiconductor chip 200a on the interposer structure 100a (operation

In operation S2400, the semiconductor chip 200a may be mounted on the interposer insulating layer 160a of the interposer structure 100a. According to an embodiment, in operation S2400, the chip pad 220a of the semiconductor chip 200a may be accommodated in the insulating hole 160a_H of the interposer insulating layer 160a. Also, the chip pad 220a of the semiconductor chip 200a may contact the chip connection terminal 150 exposed by the insulating hole 160a_H.

According to an embodiment, in operation S2400, the chip pad 220a of the semiconductor chip 200a may be integrated with the chip connection terminal 150 of the interposer structure 100a via a thermal compression bonding process.

According to an embodiment, the interposer structure 100a may support the lower portion of the semiconductor chip 200a. In detail, the top surface of the interposer insulating layer 160a of the interposer structure 100a may support the bottom surface of the semiconductor substrate 210a of the semiconductor chip 200a. The interposer insulating layer 160a is able to support the semiconductor chip 200a, and thus structural reliability of the semiconductor package may be improved.

Also, the chip pad 220a of the semiconductor chip 200a is in the insulating hole 160a_H of the interposer insulating layer 160a, and the top surface of the interposer insulating layer 160a is able to contact the bottom surface of the semiconductor substrate 210a, and thus the size of the semiconductor package manufactured via the method according to the inventive concept may be decreased.

Referring to FIG. 13E, the method according to an embodiment of the inventive concept may include forming the molding layer 300 on the interposer insulating layer 160a (operation S2500).

According to an embodiment, in operation S2500, the molding layer 300 may be at the upper portion of the interposer insulating layer 160a and cover the side and top surfaces of the semiconductor chip 200a. However, an embodiment is not limited thereto, and the molding layer 300 may be at the upper portion of the interposer insulating layer 160a, cover the side surface of the semiconductor chip 200a, and expose the top surface of the semiconductor chip 200a.

By performing operations S2100 through S2500, manufacturing of the semiconductor package 20 according to an embodiment of the inventive concept may be completed.

While the inventive concept has been particularly shown and described with reference to embodiments thereof, it will be understood that various changes in form and details may be made therein without departing from the spirit and scope of the following claims.

What is claimed is:

1. An interposer structure comprising:
an interposer substrate;
an interposer through electrode extending into the interposer substrate in a vertical direction;
a redistribution structure on the interposer substrate comprising a redistribution pattern connected to the interposer through electrode and a redistribution insulating layer on the interposer substrate and side surfaces of the redistribution pattern;
a conductive post on the redistribution structure and connected to the redistribution pattern; and
an interposer insulating layer on the redistribution structure and side surfaces of the conductive post.

2. The interposer structure of claim 1, further comprising a chip connection terminal on the conductive post.

3. The interposer structure of claim 2, wherein a top surface of the interposer insulating layer and a top surface of the chip connection terminal are coplanar.

4. The interposer structure of claim 2, wherein the interposer insulating layer comprises an insulating hole exposing at least a portion of the chip connection terminal.

5. The interposer structure of claim 2, wherein a sum of lengths of the conductive post and chip connection terminal in thevertical direction is 10 micrometers to 50 micrometers.

6. The interposer structure of claim 1, wherein the conductive post comprises:
a first conductive post on the interposer insulating layer and having a first length in the vertical direction; and
a second conductive post on the interposer insulating layer and having a second length in the vertical direction that is less than the first length.

7. The interposer structure of claim 6, further comprising:
a first chip connection terminal on the first conductive post; and
a second chip connection terminal on the second conductive post,
wherein a top surface of the interposer insulating layer is coplanar with a top surface of the first chip connection terminal, and the interposer insulating layer comprises an insulating hole exposing at least a portion of the second chip connection terminal.

8. The interposer structure of claim 2, wherein a material of the conductive post comprises at least one of copper (Cu) and nickel (Ni), and a material of the chip connection terminal comprises tin (Sn).

9. A semiconductor package comprising:
an interposer structure comprising: an interposer substrate; an interposer through electrode extending into the interposer substrate in a vertical direction; a redistribution structure on the interposer substrate comprising a redistribution pattern connected to the interposer through electrode and a redistribution insulating layer on the interposer substrate and side surfaces of the redistribution pattern; a conductive post on the redistribution structure and connected to the redistribution pattern; a chip connection terminal on the conductive post; and an interposer insulating layer on the redistribution structure and side surfaces of the conductive post and the chip connection terminal;
a semiconductor chip on the interposer structure and comprising: a semiconductor substrate including an active layer; and a chip pad on at a lower portion of the semiconductor substrate, connected to the active layer, and contacting the chip connection terminal; and
a molding layer on the interposer structure and the semiconductor chip.

10. The semiconductor package of claim 9, wherein a top surface of the interposer insulating layer and a top surface of the chip connection terminal are coplanar.

11. The semiconductor package of claim 10, wherein a bottom surface of the semiconductor substrate and the top surface of the interposer insulating layer are spaced apart in the vertical direction, and the molding layer is between the bottom surface of the semiconductor substrate and the top surface of the interposer insulating layer.

12. The semiconductor package of claim 9, wherein a top surface of the interposer insulating layer is at a higher level than a top surface of the chip connection terminal.

13. The semiconductor package of claim 12, wherein the top surface of the interposer insulating layer and a bottom surface of the semiconductor substrate are coplanar.

14. The semiconductor package of claim 9, wherein a cross-section of the conductive post in a horizontal direction comprises at least one shape from among a circular shape, a rectangular shape, and an octagonal shape.

15. The semiconductor package of claim 9, wherein a length of the chip pad of the semiconductor chip in the vertical direction is 1 micrometer to 5 micrometers.

16. The semiconductor package of claim 9, wherein a side surface of the molding layer, a side surface of the interposer insulating layer, a side surface of the redistribution structure, and a side surface of the interposer substrate are on a same plane.

17. A semiconductor package comprising:
a package substrate;
an interposer structure on the package substrate comprising: an interposer substrate; an interposer through electrode extending into the interposer substrate in a vertical direction; a redistribution structure on the interposer substrate comprising a redistribution pattern connected to the interposer through electrode and a redistribution insulating layer on the interposer substrate and side surfaces of the redistribution pattern; a conductive post on the redistribution structure and connected to the redistribution pattern; a chip connection terminal on the conductive post; an interposer insulating layer on the redistribution structure and side surfaces of the conductive post and the chip connection terminal; and an interposer connection terminal on a lower portion of the interposer substrate and connected to the package substrate;
a semiconductor chip on the interposer structure comprising: a semiconductor substrate including an active layer; and a chip pad on a lower portion of the semiconductor substrate, connected to the active layer, and contacting the chip connection terminal;
a molding layer on the interposer structure and contacting side surfaces of the semiconductor chip; and
an underfill layer between the interposer substrate and the package substrate, and side surfaces of the interposer connection terminal.

18. The semiconductor package of claim 17, further comprising a heat sink on the package substrate, a side surface of the interposer structure, and a side surface and top surface of the molding layer.

19. The semiconductor package of claim 17, wherein a top surface of the interposer insulating layer and a top surface of the chip connection terminal are coplanar,
a bottom surface of the semiconductor substrate is at a higher level than the top surface of the interposer insulating layer, and
the molding layer is between the bottom surface of the semiconductor substrate and the top surface of the interposer insulating layer.

20. The semiconductor package of claim 17, wherein a top surface of the interposer insulating layer is at a higher level than a top surface of the chip connection terminal, and
the top surface of the interposer insulating layer and a bottom surface of the semiconductor substrate are coplanar.
